(19) United States
(12) Patent Application Publication
(10) Pub. No.: US 2024/0178231 A1
(43) Pub. Date: May 30, 2024

(54) MICROELECTRONIC DEVICE WITH IMPROVED VERTICAL BREAKDOWN VOLTAGE

(71) Applicant: COMMISSARIAT A L'ENERGIE ATOMIQUE ET AUX ENERGIES ALTERNATIVES, Paris (FR)

(72) Inventors: Gennie GARNIER, Grenoble Cedex 09 (FR); Romain GWOZIECKI, Grenoble Cedex 09 (FR); Charlotte GILLOT, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/510,858

(22) Filed: Nov. 16, 2023

(30) Foreign Application Priority Data
Nov. 30, 2022 (FR) 22 12586

(51) Int. Cl. H01L 27/12; H01L 23/48; H01L 29/786

(52) U.S. Cl. CPC H01L 27/1203; H01L 23/481; H01L 29/78681

(57) ABSTRACT

A microelectronic device including a first transistor including a first active layer, a second field effect transistor including a second active layer, the second source being electrically connected to the first drain, a first rear electrode and a second rear electrode. The device in addition includes an insulating layer extending, between the first rear electrode and the first active layer, on the one hand, and the second rear electrode and the second active layer, on the other hand. The insulating layer is continuous and has a critical field E_{c} and a thickness called dielectric thickness e₁₅₀₀ of between 2*e_{1500,min} and 10*e_{1500,min}, with e_{1500,min}=V_{target}/E_{c}, V_{target} being a target breakdown voltage of the insulating layer, the first dielectric having a heat conductivity λ₁ greater than 1 W·m⁻¹·K⁻¹.

### TECHNICAL FIELD

The present invention relates to the field of microelectronic devices, in particular, on silicon epitaxially grown GaN-based components. It has, for example, a particularly advantageous application in the field of power electronics.

### PRIOR ART

Transistors, for example, transistors composed of GaN epitaxially grown on silicon (commonly called “GaN-on-Si” transistors), generally have three contacts: a source, a gate and a drain. In the specific scope of integrating several lateral components epitaxially grown on a heterogeneous substrate, such as several GaN-on-Si transistors, it is well-known, given the architecture of the properties of the different layers constituting the components, that it is necessary that the potential of the substrate of each of the components is equivalent to that of its source. This indeed makes it possible to limit the so-called “current collapse” phenomena, which is are conveyed by a significant increase in the resistance in the on-state after a high-voltage blocking. It thus appears that the integration of several components cannot be done on one same substrate, the potential of which would be common to all the components. This is, in particular, the case for “bridge arm”-type devices, integrating two components in series.

There are different solutions enabling the manufacture of devices integrating several components.

Approaches aiming to replace the silicon substrate with a thick electrical insulator (for example, of several microns), even a very good heat conductor, also have the impact of reducing the impact of the bias of the substrate on the distribution of the potential within the device, which can be equivalent to the fact of having a floating substrate potential. This effect is well-documented in the scope of SOI-type devices with thick buried oxide (see, in particular: Q. Xie, C. Lee, J. Xu, C. Wann, J. Y. -. Sun et Y. Taur, “Comprehensive Analysis of Short-Channel Effects in Ultrathin SOI MOSFETs,” in IEEE Transactions on Electron Devices, vol. 60, no. 6, pp. 1814-1819, June 2013). This has the consequence of worsening the “current collapse” phenomena.

The document, GaN Integrated Bridge Circuits on Bulk Silicon Substrate: Issues and Proposed Solution, Jin Wei, Meng Zhang, Gang Lyu and Kevin Chen proposes an approach making it possible, for example, to insulate the components from one another and to ensure a bias independent of each one, but at the expense of adding additional silicon layers which could negatively impact the heat resistance and potentially adding additional interfering capacities. The vertical breakdown voltage is, however, always ensured by the epitaxially-grown GaN layers.

Other approaches (see again, GaN Integrated Bridge Circuits on Bulk Silicon Substrate: Issues and Proposed Solution, Jin Wei, Meng Zhang, Gang Lyu and Kevin Chen) aim to use a median or variable potential, but this non-ideal bias is conveyed, for example, by “current collapse”-type problems.

Another solutions consists of forming a stack of the different layers which will constitute the single components, and forming trenches in this stack, making it possible to individualise the components. The different components can all extend from a common base left intact during the formation of the trenches.

Each of the single components thus typically has the following structure:
a substrate,
buffer layers making it possible to adjust the stresses between the mesh differences of the material constituting the substrate and of the material with the basis of the active layers,
the active layers of the component.

In the specific scope of a GaN-on-Si component, the substrate is conductive. Thus, the breakdown voltage between this and the drain contact (which will be biased at the high voltage, typically 100V, 200V, 650V, 1200V or more, according to the component class) is conditioned by the insulating properties of the buffer layers. These buffer layers must, in particular, have the following features:
The capacity to keep the maximum voltage which will be applied on the component, whether for brief times or very long durations.
The capacity to have a low leakage current, i.e. to act as the maximum, like a dielectric insulator.

Another important aspect is that the buffer layers are generally connected to the radiator linked to the casing of the device, in order to discharge the heat generated during the operation of the component, in particular the resistive losses and the switching losses. Thus, it is desirable that these buffer layers have a high heat conductivity. This makes it possible to discharge the heat contained in the device more easily, and to limit the heating leading to the degradation of the performance of the component, and more generally, its overall degradation.

However, the buffer layers enabling the adjustment of the stresses between the substrate and the active layers of the components do not always have the properties enabling both a good breakdown voltage of the components, and a good heat discharge.

The article, Monolithically Integrated GaN Power ICs—The demonstration of half-bridges and single-stage buck converters takes GaN power ICs another step forward by Xiangdong Li and Stefaan Decoutere presents the results obtained for a device of the type which has just been described. The solution presented in this article makes it possible to theoretically insulate the components from one another and the independently bias each of the rear faces of the components, by including an insulating layer between a silicon support substrate and a nucleation silicon layer of the epitaxy of the active layers, by laterally insulating the components from one another, thanks to trenches. The nucleation layer is also connected to the source thanks to a through contact. However, this solution does not operate for devices needing to support high voltages (i.e. greater than 200V), as the epitaxial thicknesses of GaN layers on an SOI substrate necessary for the vertical breakdown voltage induce mechanical stresses which are too high.

Document US 2013/146946 A1 has a structure integrating several lateral components. However, this document does not resolve the breakdown voltage problems of the components.

An aim of the present invention is thus to propose a microelectronic device integrating several single components and having both a good breakdown voltage and a good heat discharge.

### SUMMARY

To achieve this aim, according to an embodiment, a microelectronic device is provided, comprising:
a first field effect transistor comprising a first active layer, as well as a first drain, a first source, a first gate surmounting the first active layer,
a second field effect transistor comprising a second active layer, as well as a second drain, a second source and a second gate surmounting the second active layer, the second source being electrically connected to the first drain,
a first rear electrode, underlying the first active layer in a stack direction perpendicular to a transverse plane defined by a first direction and a second direction, the first rear electrode being electrically connected to the first source,
a second rear electrode, underlying the second active layer in the stack direction, the second rear electrode being separated from the first rear electrode, the second rear electrode being electrically connected to the second source,
a stack.

The stack comprises, in particular:
a third continuous and GaN-based layer, underlying the first active layer, on the one hand, and underlying the second active layer, on the other hand, and
an insulating layer extending, in the stack direction, between the first rear electrode and the first active layer, on the one hand, and the second rear electrode and the second active layer, on the other hand, the insulating layer being continuous and with the basis of a first dielectric, the insulating layer having, in the stack direction, a critical field E_{c}, the insulating layer having, in the stack direction, a thickness called dielectric thickness e1500 of between 2*e_{1500,min} and 10*e_{1500,min}, with e_{1500,min}=V_{target}/E_{c}, V_{target} being a target breakdown voltage of the insulating layer, the first dielectric having a heat conductivity λ1 greater than 1 W·m⁻¹·K⁻¹.

The layer ensuring the vertical breakdown voltage in the device is, in this case, the insulating layer. Its thickness is sized so as to optimise this breakdown. It makes it possible, in particular, to guarantee that the device resists the application of any voltage less than the target breakdown voltage V_{target}. This target breakdown voltage V_{target} of the insulating layer is indicated on the specification sheet.

The heat conductivity level of the first dielectric further makes it possible to guarantee a good discharge of the heat contained in the device.

The invention therefore takes advantage of the electrical and heat properties of dielectrics.

### BRIEF DESCRIPTION OF THE FIGURES

The aims, objectives, as well as the features and advantages of the invention will best emerge from the detailed description of an embodiment of the latter, which is illustrated by the following accompanying drawings, wherein:

FIG. 1 represents a device according to the prior art integrating two single components.

FIG. 2A represents a cross-sectional view of an embodiment of the device according to the invention.

FIG. 2B represents a cross-sectional view of an embodiment of the device according to the invention, wherein the electrical connection between the source and the rear electrode of each of the transistors is ensured by electrical connection elements passing through the stack of the device.

FIG. 2C represents a top view of an embodiment of the device according to the invention.

FIG. 2D represents a cross-sectional view of an embodiment of the device according to the invention.

FIG. 3A illustrates the good vertical breakdown voltage of the device and the weak lateral coupling between the two transistors of the component when the different layers of the device are correctly sized.

FIG. 3B illustrates the poor vertical breakdown voltage of the device and the significant lateral coupling between the two transistors of the component when the thickness of the insulating layer of the device is too thick.

FIGS. 4A to 4E represent a first embodiment of a method for manufacturing the device according to the invention.

FIGS. 5A to 5M represent a second embodiment of a method for manufacturing the device according to the invention.

FIG. 6 illustrates a device according to an embodiment of the invention, comprising, in particular, a layer for adjusting the stresses of the buffer layer.

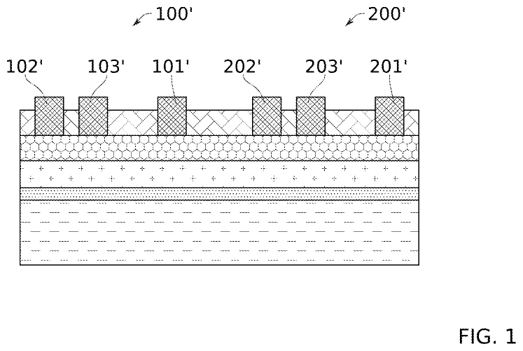

The drawings are given as examples and are not limiting of the invention. They constitute principle schematic representations, intended to facilitate the understanding of the invention, and are not necessarily to the scale of practical applications. In particular, the dimensions are not representative of reality.

### DETAILED DESCRIPTION

Before starting a detailed review of embodiments of the invention, below optional features are stated, which can optionally be used in association or alternatively:

According to an advantageous example, V_{target}≥900V.

According to an embodiment, in the transverse plane, the first rear electrode and the second rear electrode are separated by a lateral insulation distance dᵢₙₛ greater than 50 μm, preferably greater than 100 μm.

According to an advantageous embodiment, projecting in the transverse plane and in any direction of the transverse plane:
the first rear electrode projects with respect to the first active layer over a first overflow distance d_{over,1}, with d_{over,1}>0, and
the second rear electrode projects with respect to the second active layer over a second overflow distance d_{over,2}, with d_{over,2}>0.

According to an example, in the stack direction, the third active layer has a thickness called active thickness e₁₁₀₀, and d_{over,1}≥e₁₁₀₀+e₁₅₀₀ and d_{over,2}≥e₁₁₀₀+e₁₅₀₀.

According to an advantageous example, the stack has a thickness e₁₀₀₀ in the stack direction, with d_{over,1}≥e₁₀₀₀ and d_{over,2}≥₁₀₀₀.

According to an embodiment, the first dielectric is one from among AlN, SiO₂, Al₂O₃, Si₃N₄, HfO₂ and diamond.

According to an embodiment, the device further comprises a first electrical connection element passing through the stack and electrically connecting the first source to the first rear electrode.

According to an embodiment, the device further comprises a second electrical connection element passing through the stack and electrically connecting the second source to the second rear electrode.

According to an example, e₁₅₀₀≥1 μm, preferably e₁₅₀₀≥2 μm.

According to an embodiment, the third active layer is directly in contact with the first active layer and with the second active layer.

It is specified that, in the scope of the present invention, the terms “on”, “surmounts”, “covers”, “underlying”, “opposite” and their equivalents do not necessarily mean “in contact with”. Thus, for example, the deposition, the transfer, the bonding, the assembly, or the application of a first layer on a second layer, does not compulsorily mean that the two layers are directly in contact with one another, but means that the first layer at least partially covers the second layer by being, either directly in contact with it, or by being separated from it by at least one other layer or at least one other element.

A layer can moreover be composed of several sublayers of one same material or of different materials.

By a substrate, a layer, a device “with the basis” of a material M, this means a substrate, a layer, a device comprising this material M only or this material M and optionally other materials, for example alloy elements, impurities, or doping elements. Thus, a material with the basis of a III-N material can comprise a III-N material added with dopants. Likewise, a GaN-based layer typically comprises GaN and AlGaN or InGaN alloys.

The term “III-V material” makes reference to a semiconductor composed of one or more elements of column III and of column V of Mendeleev's periodic table. Among the elements of column III, there are boron, gallium, aluminium or also indium. Column V contains, for example, nitrogen, arsenic, antimony and phosphorus.

The critical electric field of an insulating medium, also called dielectric rigidity, represents the maximum value that the medium in question can support before the triggering of an electric arc (breakdown of the insulator). This feature is expressed in V/m, or more commonly in kV/mm or MV/m. For an insulating medium to which a voltage V is applied to the two electrodes, the critical electric field is expressed as follows:

$${E}_{c} = \frac{{V}_{c}}{d} \qquad [ Math 1 ]$$

with V_{c} the breakdown voltage, i.e. the voltage at which a short-circuit occurs between the electrodes, and d the distance between the electrodes.

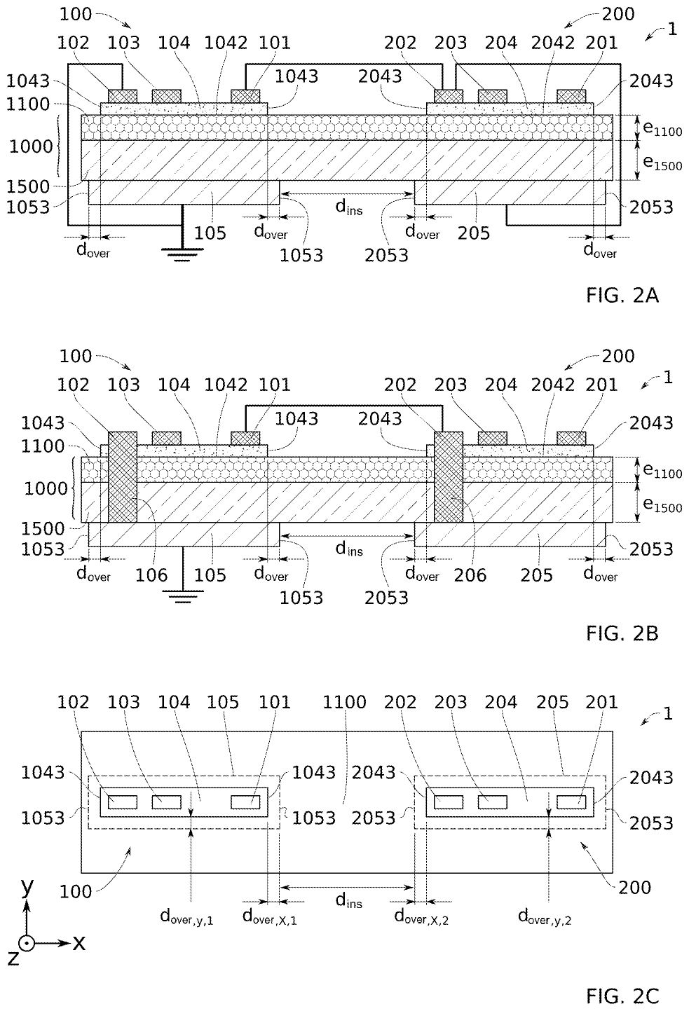

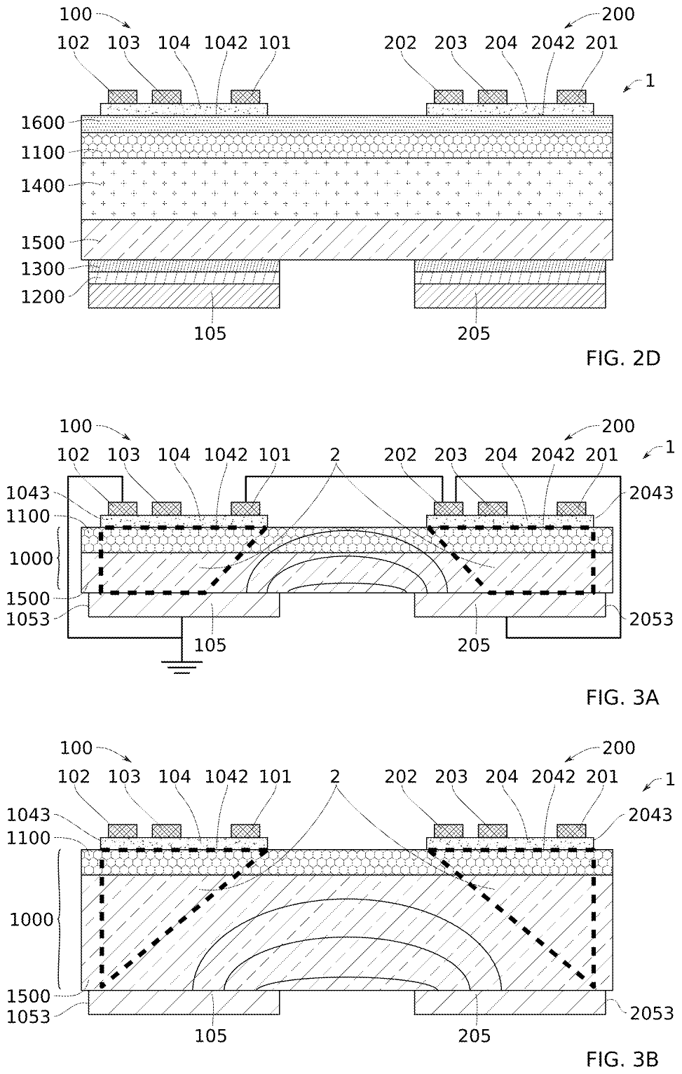

A preferably orthonormal system, comprising the axes X, Y, Z is represented in FIG. 2A. This system is applicable by extension to the other figures.

In the present patent application, thickness will preferably be referred to for a layer and height for a structure or a device. The height is taken perpendicularly to the transverse plane XY. The thickness is taken in a direction normal to the main extension plane of the layer. Thus, a layer typically has a thickness along Z, when it extends mainly along the transverse plane XY, and a projecting element, for example an insulation trench, has a height along Z. The relative terms “on”, “under”, “underlying” preferably refer to positions taken along the direction Z.

The terms “substantially”, “about”, “around” mean “plus or minus 10%, preferably plus or minus 5%”.

The device according to different embodiments of the invention will now be described in reference to FIGS. 2A to 2C.

The device 1 comprises at least two field effect transistors 100, 200.

The first transistor 100 comprises a first active layer 104. This first active layer 104 is surmounted by a first drain 101, a first source 102 and a first gate 103 of the first transistor 100. The first transistor 100 further comprises a first rear electrode 105 underlying the first active layer 104. In the same way, the second transistor 200 comprises a second active layer 204 surmounted by a second drain 201, a second source 202 and a second gate 203. It also comprises a second rear electrode 205 underlying the second active layer 204.

The first and second rear electrodes 105, 205 enable, in particular, an electrostatic control of the device 1. They can be assimilated respectively to a first rear gate and a second rear gate of the device 1.

The active layers 104, 204 are typically with the basis of a semiconductive material, for example, a III-V material, preferably a III-N material, for example, GaN or a material of the Al₁₋ₓGaₓN type (with x varying from 0 to 1).

In order to limit the “current collapse” phenomena, the source 102, 202 and the rear electrode 105, 205 of each transistor 100, 200 are advantageously electrically connected. Moreover, the first drain 101 of the first transistor 100 is typically electrically connected to the second source 202 of the second transistor 200. The first transistor 100 and the second transistor 200 thus form a so-called bridge arm component. In this configuration, the first transistor 100 is commonly called “low-side transistor”. In the same way, the second transistor 200 can be called “high-side transistor”.

Two elements are called “electrically connected”, when they are each in contact with one same continuous electrical connection element having an electrical conduction, preferably greater than 10⁷ S/m.

The device 1 moreover comprises a stack 100 extending, in the third direction Z:
On the one hand, between the first active layer 104 and the first rear electrode 105 of the first transistor 100, and
On the other hand, between the second active layer 204 and the second rear electrode 205 of the second transistor 200.

The stack 1000 has a thickness e₁₀₀₀ in the third direction Z.

The stack 1000 is typically continuous, in particular in the transverse plane XY, between the two transistors 100, 200.

The stack 1000 can comprise a plurality of layers stacked in the third direction Z. It comprises, in particular, an insulating layer 1500 with the basis of a first dielectric. The insulating layer 1500 is one-piece, i.e. continuous, between the two transistors 100, 200 in the transverse plane XY.

The first dielectric can, for example, be an oxide (SiO₂, Al₂O₃, HfO₂, etc.).

The first insulating layer 1500 has, in the third direction Z, a thickness e₁₅₀₀. It also has, in this same direction, a breakdown voltage V_{c} and a critical field E_{c}.

The first insulating layer 1500 must be sufficiently thick to enable a good vertical breakdown voltage of the device 1. To do this, a minimum thickness e_{1500,min} of the insulating layer 1500 is defined, corresponding to the thickness for which a short-circuit between the active layer 104, 204 of one of the transistors 100, 200 and its rear electrode 105, 205 occurs, at a target breakdown voltage fixed according to the targeted applications for the device 1. The target breakdown voltage is found in the specifications provided with the devices of this type. This minimum thickness is defined by the following relationship: e_{1500,min}=V_{target}/E_{c}, V_{target} being the target value for the breakdown voltage. In practice, the actual breakdown voltage V_{c}, of the insulating layer 1500, will be greater than the target breakdown voltage V_{target}. The target breakdown voltage V_{target} of the insulating layer is indicated on the specification sheet of the device.

The insulating layer 1500 is therefore sized, such that its thickness e₁₅₀₀ is greater than e_{1500,min}. In this way, the device 1 can resist any voltage less than the target breakdown voltage being applied to it. The thickness e_{1500,min} corresponds to the instantaneous breakdown voltage of the device 1. However, in order to guarantee a better breakdown over time, in particular a breakdown in the time compatible with the typical service life of the applications considered for the device 1, a thickness e₁₅₀₀ greater than e_{1500,min} is opted for, for example, greater than 2*e_{1500,min}. This makes it possible to obtain that the device 1 has a service life of the device 1 typically greater than 10 years for the target breakdown voltage.

Given what is said above, the thickness e₁₅₀₀ of the insulating layer 1500 is advantageously less than 20*e_{1500,min}, preferably 10*e_{1500,min}. Thus, by limiting the thickness of the insulating layer 1500, a good vertical bias of the device 1 is guaranteed. Indeed, it is necessary that the potential of the substrate has an actual control over the bias of the active layers of the device 1, and thus limit the current collapse effects.

A thickness e₁₅₀₀ of between 2*e_{1500,min} and 10*e_{1500,min} appears the best compromise between a sufficiently thick dielectric to guarantee the service life and sufficiently thin to maximise the bias on the rear face of the component. For the same reasons, the range between 2*e_{1500,min} and 5*e_{1500,min} is particularly advantageous. e₁₅₀₀ can also be greater than 5*e_{1500,min}, which makes it possible to also maximise the service life or to minimise the risks of early breakdown.

FIGS. 3A and 3B respectively illustrate a case, wherein the vertical bias of the device 1 is ensured and a case, wherein the lateral coupling takes precedence over the vertical bias. In these two figures, the hatched zones 2 represent the electrostatic impact zones of the rear electrode on the active layers 104, 204 of the two transistors 100, 200, and generally on the device 1. The lines, in particular connecting the first rear electrode 105 and the second rear electrode 205, are the field lines: they illustrate the lateral breakdown voltage—or lateral coupling—between the two transistors 100, 200. A good balance between vertical bias and lateral breakdown voltage must be found. It is observed in FIG. 3A, that the impact of the rear electrodes 105, 205 on the active zones is optimal. The lateral coupling only interferes a little on the vertical bias. The electrostatic integrity of the device 1 is therefore preserved. Conversely, in FIG. 3B, the rear electrodes 105, 205 have almost no electrostatic impact on the device. The thickness of the insulating layer 1500 is too thick to guarantee the vertical bias. The lateral coupling is too much to guarantee a good operation of the device 1. The electrostatic integrity of the device 1 is not preserved, in this case.

As an example, for a device 1 needing to operate at a voltage of 650V, it is common to look for the device 1 to have a breakdown voltage greater than 900V, for example 1000V. The target breakdown voltage is therefore 1000V, in this example. Table 1 gives ranges of thicknesses e₁₅₀₀ possible for different dielectrics which can be considered for the first dielectric:

TABLE

| | | | |
|---|---|---|---|
| First | Theoretical | | Example of possible |
| dielectric | E_{c} | e_{1500, min} | range for e_{1500, min} |

| | | | | | |
|---|---|---|---|---|---|
| SiO₂ | 12 | MV/cm | 0.8 | μm | 1-10 μm |
| Al₂O₃ | 8-10 | MV/cm | 1-1.2 | μm | 1-10 μm |
| Si₃N₄ | 10-12 | MV/cm | 0.8-1 | μm | 1-10 μm |
| HfO₂ | 5-6 | MV/cm | 1.6-2 | μm | 2-20 μm |

A criterion for selecting the first dielectric can thus be the value of its theoretical critical electrical field.

The first dielectric has, in addition, an electrical conductivity referenced σ₁. The latter is preferably less than 10⁻¹⁷ Ω⁻¹.m⁻¹. The fact that the vertical breakdown voltage is mainly ensured by the insulating layer 1500 makes it possible to reduce the leakage current of the device 1. The dielectrics indeed have electrical conductivity values less than those of the materials commonly used for the epitaxially grown layers of the components, layers usually serving the vertical breakdown voltage. The invention therefore makes it possible to take advantage of the advantageous electrical conduction values of the dielectrics. Preferably, the thickness e₁₅₀₀ and the electrical conductivity σ₁ of the insulating layer 1500 are such that the leakage current is less than 1 μA/cm² at the maximum application voltage (example: 650V). The invention can even enable leakage current levels as low as 1 nA/cm².

The first dielectric moreover has a heat conductivity λ₁ greater than 1 W·m⁻¹·K⁻¹, preferably greater than 30 W·m⁻¹·K⁻¹. Such a heat conductivity level enables a good discharge of the heat contained in the device 1.

The electrical and heat conductivities of the material can thus constitute other selection criteria of the first dielectric.

The stack 1000 moreover comprises a third active layer 1100, underlying the first and second active layers 104, 204. This third active layer 1100 is preferably itself also continuous under and between the two transistors 100, 200. It is located above the insulating layer 1500 in the third direction Z. It can, for example, be in contact with the lower face 1042 of the first active layer 104 and of the lower face 2042 of the second active layer 204.

The third active layer 1100 is preferably with the basis of a III-V material, for example, a III-N material. This can, for example, be carbon doped GaN.

The third active layer 1100 partially ensures the lateral breakdown voltage of the device 1. The typically thicknesses of this layer are 1 to 4 μm, with a carbon doping typically of between 10¹⁸ and 5·10¹⁹ atom/cm³.

The stack can also comprise one or more layers for adjusting the stresses of the buffer layers 1400. These layers can, for example, be Si-, SiC- or also sapphire-based.

The stack 1000 advantageously comprises a first barrier layer 1200 and an adherence layer 1300 between the first rear electrode 105 and the insulating layer 1500, on the one hand, and the second rear electrode 205 and the insulating layer 1500, on the other hand. These two layers 1200, 1300 preferably have a discontinuity between the two transistors 100, 200 in the transverse plane XY. The first barrier layer 1200 can, for example, be TIN- or TaN-based. It has, in the third direction Z, a thickness e₁₂₀₀ preferably of between 10 nm and 50 nm, for example substantially equal to 40 nm. In the case where the first barrier layer 1200 is TiN-based, the adherence layer 1300 is typically Ti-based. The adherence layer can also be Ta-based. It has, in the third direction Z, a thickness e₁₃₀₀ preferably of between 5 and 20 nm, for example, substantially equal to 10 nm.

According to a particular embodiment illustrated in FIG. 2D, the stack 1000 comprises, in the third direction Z, the following layers:
A first barrier layer 1200, in contact with the rear electrodes 105, 205,
An adherence layer 1300,
An insulating layer 1500,
One or more layers for adjusting the stresses 1400,
A third active layer 1100,
A second barrier layer 1600, in contact with the active layers 104, 204.

It is moreover perfectly considerable, that the stack 1000 comprises several insulating layers, for example, each with the basis of a different material. This can make it possible to take advantage of electrical and heat properties of different dielectric materials.

In order to guarantee the insulation of each of the biases of the substrate, the first rear electrode 105 and the second rear electrode 205 are advantageously separated in the transverse plane XY by a lateral insulation distance dᵢₙₛ, preferably being greater than 50 μm, typically greater than 100 μm. Being concerned about optimising the density of the components, dᵢₙₛ is preferably less than 300 μm.

As illustrated in FIG. 2C, the rear electrodes 105, 205 of each of the transistors are preferably, projecting in the transverse plane XY, projects with respect to the active layers 104, 204. For the first transistor 100, a first overflow distance d_{over,1} is defined, corresponding to the distance in the transverse plane XY between a flank 1043 of the first active layer 104 and a flank 1053 of the first rear electrode 105. A second overflow distance d_{over,2}, corresponding to the distance in the transverse plane XY between a flank 2043 of the second active layer 204 and a flank 2053 of the second rear electrode 205, is defined for the second transistor 200.

The overflow distances d_{over,1}, d_{over,2}, can be defined in any direction of the transverse plane XY. For example, it can be defined that, as illustrated in FIG. 2C:
in the first direction X:
   i. the first rear electrode 105 projects with respect to the first active layer 104 over a first overflow distance in the first direction d_{over,X,1},
   ii. the second rear electrode 205 projects with respect to the second active layer 204 over a second overflow distance in the first direction d_{over,X,2},
in the second direction Y:
   i. the first rear electrode 105 projects with respect to the first active layer 104 over a first overflow distance in the second direction d_{over,Y,1},
   ii. the second rear electrode 205 projects with respect to the second active layer 204 over a second overflow distance in the second direction d_{over,Y,2}.

Whatever the direction in which they are defined, the overflow distances d_{over,1}, d_{over,2} are preferably non-zero (i.e. for example, that d_{over,X,1}, d_{over,X,2}, d_{over,Y,1}, d_{over,Y,2}>0). This makes it possible to minimise the electrical field between each source 102, 202 and the rear face of the device 1. The electrostatic integrity of the transistors 100, 200 and more generally, of the device 1 is thus improved.

Advantageously, the overflow distance d_{over,1}, d_{over,2} are each greater than the sum of the thickness e₁₅₀₀ of the insulating layer and of the thickness e₁₁₀₀ of the third active layer 1100. Preferably, they are each greater than the thickness e₁₀₀₀ of the stack 1000 in its entirety. Providing such overflow distances d_{over,1}, d_{over,2} makes it possible to prevent the electrical field of a neighbouring device to impact the potential between the source and the rear face of the device 1. Thus, this gives the device 1 an optimal electrostatic integrity.

According to an advantageous embodiment of the invention, the source 102, 202 of each transistor 100, 200 is electrically connected to the rear electrode 105, 205 of the same transistor by way of an electrical connection element 106, 206 buried in the device 1. The electrical connection elements 106, 206 extend mainly in the third direction Z and pass through the stack 1000.

These electrical connection elements 106, 206 can be formed by a deep etching of the stack 1000. According to the embodiment of the device 1, these etchings can have a depth in the third direction Z, going from a few tens of nanometres to a few microns, typically between 4 and 6 μm. The electrical connection elements 106, 206 are then formed by the deposition of a metal in the cavities formed during the etching.

The device 1 according to the invention is particularly specific to the integration of electrical connection elements of this type. Indeed, the invention makes it possible to effectively and independently bias the integrated components within one same substrate, in particular by connecting the substrate of a component to its source. It is useful to perform this electrical connection within the device, through the stack 1000, and not via an external connection by the casing. This enables, in particular, a better compactness of the device 1.

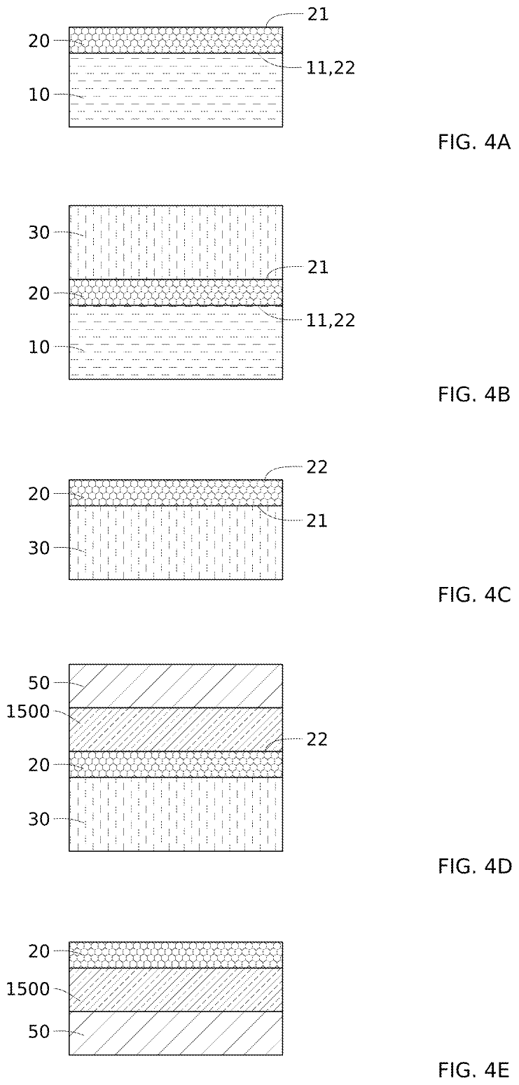

An example of a method for producing a device 1 according to the invention will now be described in reference to FIGS. 4A to 4E. This example retraces the main steps of a method for manufacturing the device 1. It is important to note that numerous intermediate steps can be implemented in addition to the steps illustrated in FIGS. 4A to 4E. This example mainly aims to illustrate key steps which could be implemented and broken down into numerous embodiments of the method according to the invention.

A first step consists of providing a substrate 10 having an upper face 11. FIG. 4A then illustrates a step of forming an active layer 20 on the upper face 11 of the substrate 10. The active layer 20 has a lower face 22 in contact with the upper face of the substrate and an upper face 21. The active layer 20 is then transformed, so as to form the desired components. The active layer 20 can, in particular, comprise in others, the first active layer 104, second active layer 204, and third active layer 1100 and have their features and technical effects.

As represented in FIG. 4B, a handle 30 is then fixed to the upper face 21 of the active layer 20. The assembly is then returned and the substrate 10 is removed, as illustrated in FIG. 4C.

An insulating layer 1500 is then deposited on the lower face 22 of the active layer 20, then a conductive layer 50 is deposited on the insulating layer 1500, thus leading to the stack illustrated in FIG. 4D. As illustrated in FIG. 4E, the handle 30 is then removed. Thus, a stack is obtained, composed of the conductive layer 50, of the insulating layer 1500 and of the active layer 20. The conductive layer 50 can then be individualised into electrodes, i.e. into rear transistor gates.

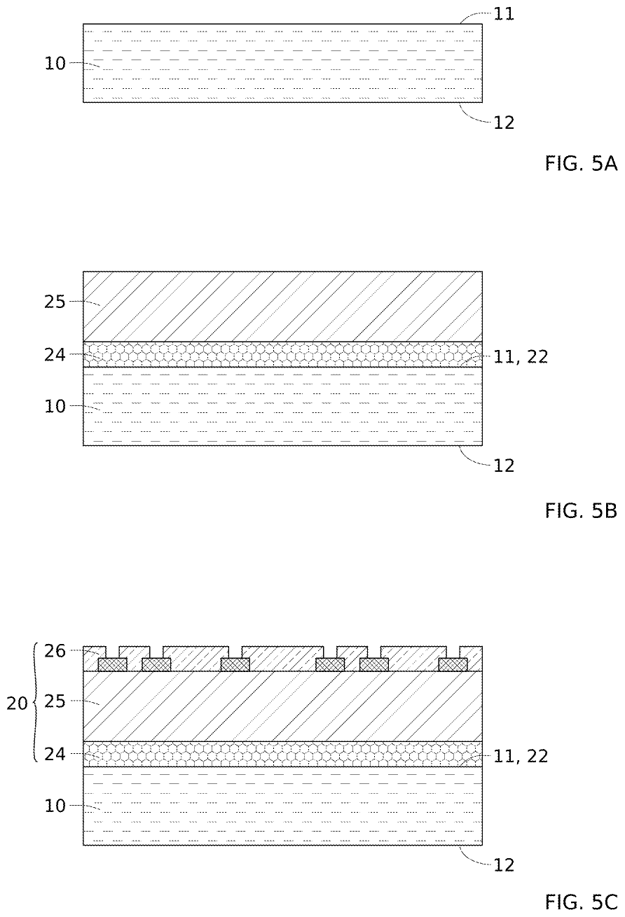

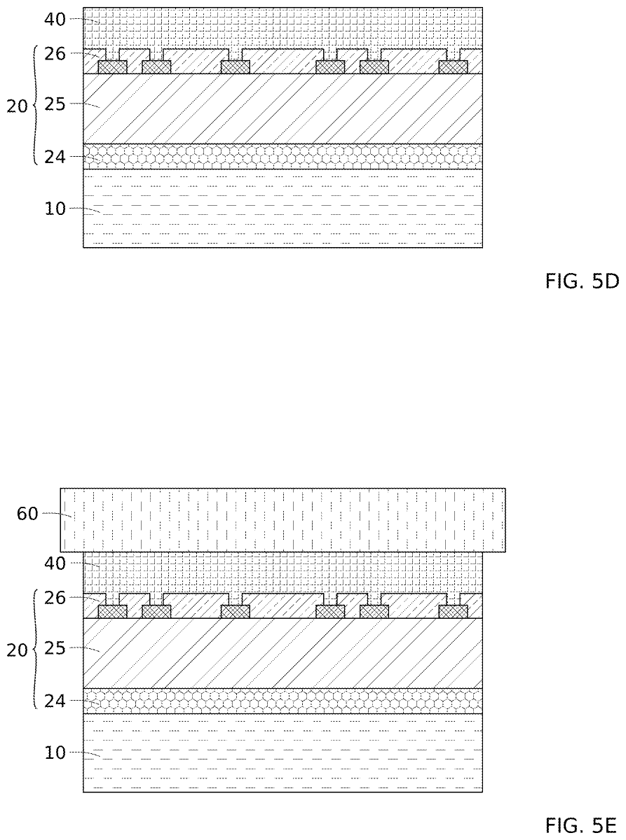

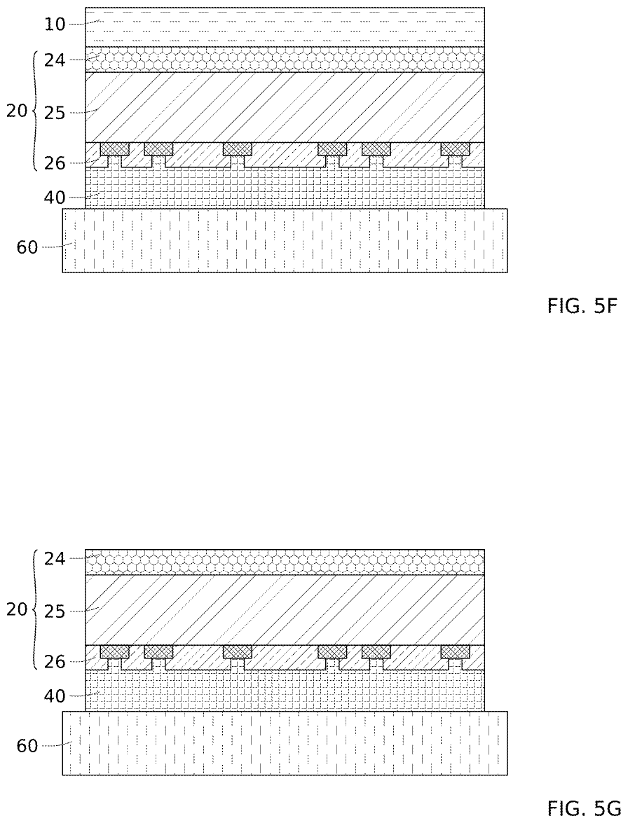

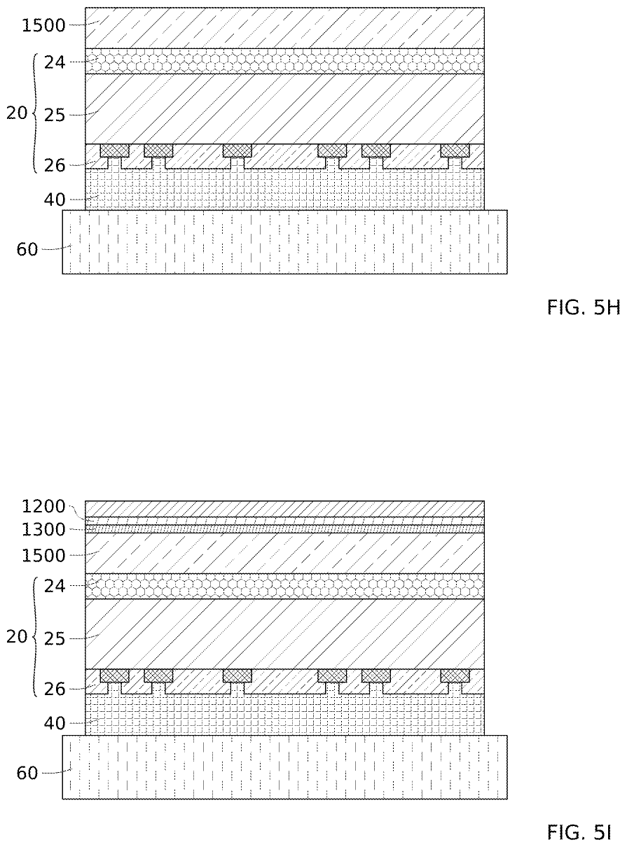

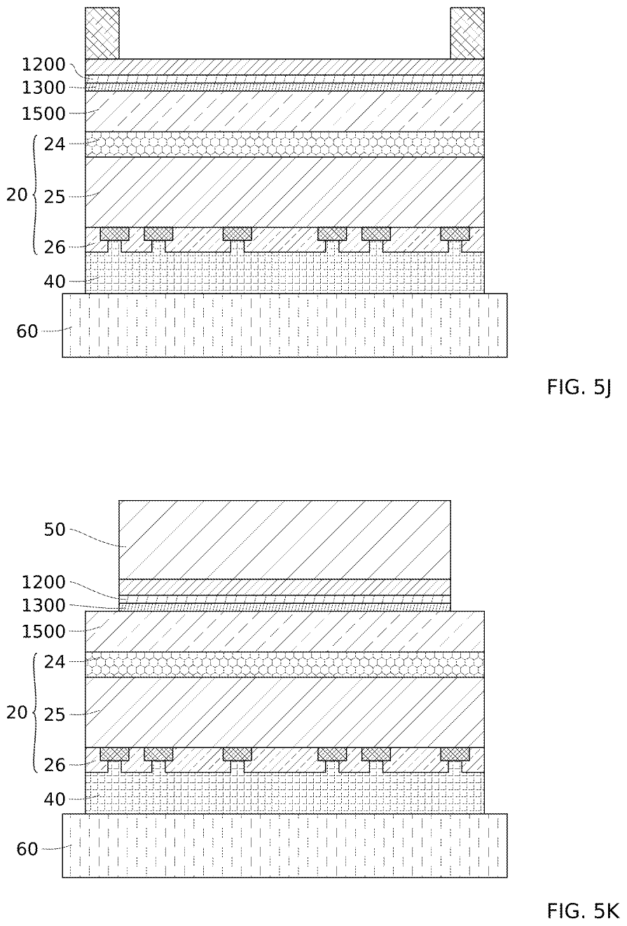

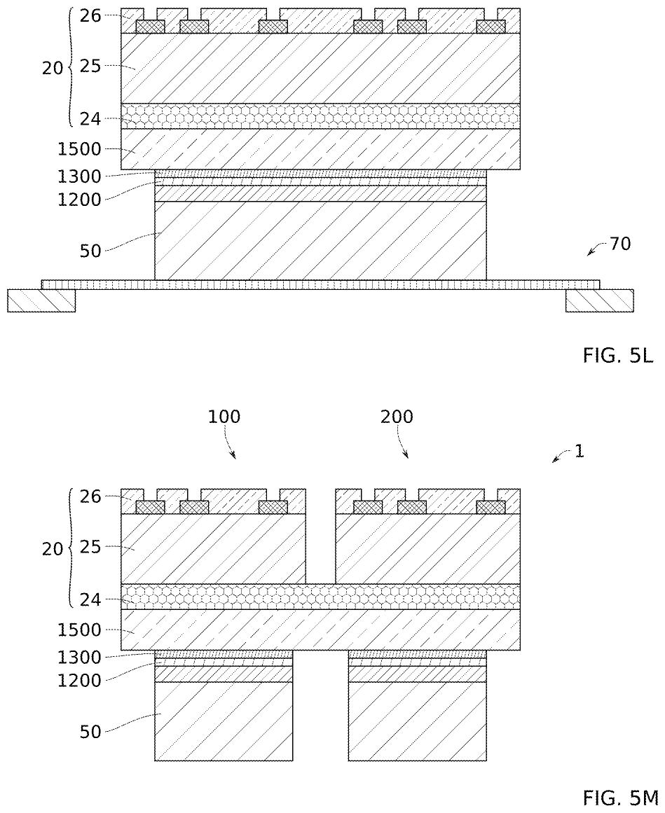

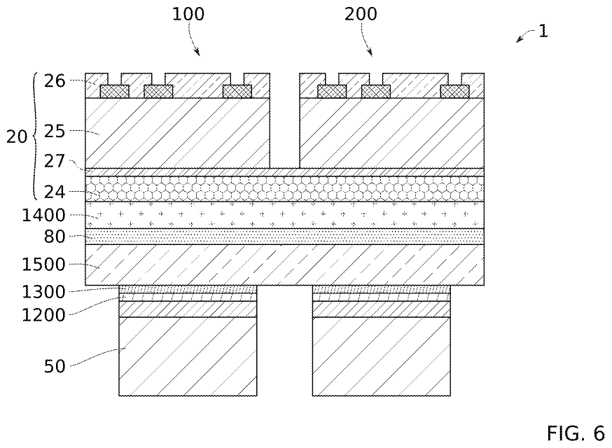

Another example of a method for producing a device 1 according to the invention will now be described in reference to FIGS. 5A to 5M.

FIG. 5A illustrates the provision of a substrate 10 having an upper face 11 and a lower face 12.

As illustrated in FIG. 5B, an epitaxy is then done from the upper face 11 of the substrate 10. During this epitaxy, the following can, in particular, be formed: a nucleation layer, one or more layers for adjusting the stresses 1400, one or more active layers 24, 25, 26 (including, for example, a carbon doped GaN-based layer), a barrier layer and a passivation layer.

As the same time as and following this step, different elements of the device 1 (for example, channels, ohmic contacts, etc.) are formed. In particular, the FEOL (Front End Of Line) and BEOL (Back End Of Line) levels of the device 1 can be achieved at this stage of the method.

The electrical connection elements 106, 206 passing through the stack 1000 can also be formed on this occasion. A selective etching of the materials of the stack 1000, stopping at the underlying substrate, in particular, makes it possible to form cavities, wherein a metal is then deposited, constituting the electrical connection elements 106, 206.

An adhesive layer 40 can then be deposited on (FIG. 5D).

The assembly is then transferred onto a second substrate 60 called handle (FIG. 5E). As illustrated by FIGS. 5E to 5G, the assembly is returned and the substrate 10 is fully removed.

An insulating layer 1500 can then be deposited on a rear face 32 of the active layer 20 (FIG. 5H).

Advantageously, this deposition is done at a low temperature. This makes it possible to preserve a good adherence of the assembly with the handle. This also makes it possible to avoid degrading the elements formed during BEOL methods implemented previously.

The deposition of the insulating layer 1500 is typically done by atomic layer deposition (ALD). This can, for example, be an Al₂O₃ ALD deposition done at less than 400° C., for example around 300° C. This deposition can also be done by plasma-enhanced chemical vapour deposition (PECVD). This can, in particular, be an SiO₂ or SIN PECVD deposition. The insulating layer 1500 can also be deposited by chemical vapour deposition (CVD). This technique is, in particular, advantageous in the case of a diamond deposition.

Other layers can then be deposited on the insulating layer 1500 (adherence layer 1300, barrier layer 1200, etc.), as represented in FIG. 5I.

FIGS. 5J and 5K illustrate the formation of a conductive layer 50 corresponding, for example, to the rear electrodes 105, 205 of the device 1. The conductive layer 50 is preferably electrochemically deposited. They are advantageously copper-based.

As illustrated in FIG. 5L, the assembly can then be again returned and deposited, at the rear face 52 of the conductive layer 50, on a support frame 70.

The method can be ended by steps of removing the handle, individualising rear electrodes from the conductive layer 50, individualising the active layer 20, individualising devices 1 and putting in the case.

FIG. 6 illustrates a device being able to be obtained by a similar method, wherein the active layer 20 comprises, in addition to the active layers 24, 25, 26, a barrier layer being able, for example, to be AlGaN-based, and further comprising a layer for adjusting the stresses 1400 and a transition layer 80, preferably AIN-based, extending between the insulating layer 1500 and the active layer 20.

Through the different embodiments described above, it clearly appears that the invention proposes a device integrating several single components meeting the needs of the industry, namely having both a good breakdown voltage and a good heat discharge.

The device according to the invention moreover has numerous other advantages relative to current devices.

To produce the device 1, contrary to the methods making it possible to obtain the current devices, it is not necessary to perform the epitaxy of a thick active layer (typically a thick GaN layer). The vertical breakdown voltage is indeed guaranteed by the insulating layer 1500 and not by the third active layer 1100. The epitaxy of the active layers can therefore be reduced to what is strictly necessary, which corresponds to the production of nucleation layers, of the channel of each of the transistors, of an optional barrier layer and optional layers for adjusting the stresses. The mechanical stresses due to the epitaxy of these elements are therefore highly reduced. Thanks to that, it is possible to produce devices according to the invention, for example, power components, on substrates of a greater diameter, in particular silicon substrates.

Moreover, the breakdown voltage and the control of the leakage level no longer being dependent on the epitaxially grown layers (typically GaN-based layers, in particular, layers containing highly carbon doped GaN), the invention makes it possible to reduce the risk of drift linked to the trappings in these layers.

The invention can also be applied to individual power components, in order to improve their breakdown voltage and managing the heat discharge.

The invention also has advantages in the scope of so-called “GaN-IC” developments, where the electrical insulation between specific power components and addressing components is beneficial.

The invention is not limited to the embodiments described above and extends to all the embodiments covered by the invention.

1. A microelectronic device comprising:
a first field effect transistor comprising a first active layer as well as a first drain, a first source, a first gate surmounting the first active layer,
a second field effect transistor comprising a second active layer as well as a second drain, a second source and a second gate surmounting the second active layer, the second source being electrically connected to the first drain,
a first rear electrode, underlying the first active layer in a stack direction (Z) perpendicular to a transverse plane (XY) defined by a first direction (X) and a second direction (Y), the first rear electrode being electrically connected to the first source,
a second rear electrode, underlying the second active layer in the stack direction (Z), the second rear electrode being separated from the first rear electrode, the second rear electrode being electrically connected to the second source,
a stack,
wherein the stack comprises:
a continuous and GaN-based third active layer, underlying the first active layer, on the one hand, and underlying the second active layer, and
an insulating layer extending, in the stack direction (Z), between the first rear electrode and the first active layer, and between the second rear electrode and the second active layer, insulating layer being continuous and with the basis of a first dielectric, the insulating layer having, in the stack direction (Z), a critical field E_{c}, the insulating layer having, in the stack direction (Z), a thickness called dielectric thickness e₁₅₀₀ of between 2*e_{1500,min} and 10*e_{1500,min}, with e_{1500,min}=V_{target}/E_{c}, V_{target} being a target breakdown voltage of the insulating layer, the first dielectric having a heat conductivity λ₁ greater than 1 W·m⁻¹·K⁻¹.

2. The device according to claim 1, wherein V_{target}≥900V.

3. The device according to claim 1, wherein, in the transverse plane (XY), the first rear electrode and the second rear electrode are separated by a lateral insulation distance dᵢₙₛ greater than 50 μm.

4. The device according to claim 1, wherein, projecting in the transverse plane (XY) and in any direction of the transverse plane (XY):
the first rear electrode projects with respect to the first active layer over a first overflow distance d_{over,1}, with d_{over,1}>0, and
the second rear electrode projects with respect to the second active layer over a second overflow distance d_{over,2}, with d_{over,2}>0.

5. The device according to claim 4, wherein the stack has a thickness e₁₀₀₀ in the stack direction (Z), with d_{over,1}≥e₁₀₀₀ and d_{over,2}≥e₁₀₀₀.

6. The device according to claim 1, wherein the first dielectric is one from among AlN, SiO₂, Al₂O₃, Si₃N₄, HfO₂ and diamond.

7. The device according to claim 1, further comprising a first electrical connection element passing through the stack and electrically connecting the first source to the first rear electrode.

8. The device according to claim 1, further comprising a second electrical connection element passing through the stack and electrically connecting the second source to the second rear electrode.

9. The device according to claim 1, wherein e₁₅₀₀≥1 μm.

10. The device according to claim 1, wherein the third active layer is directly in contact with the first active layer and with the second active layer.
